(19) United States
(12) Patent Application Publication
(10) Pub. No.: US 2021/0343540 A1
(43) Pub. Date: Nov. 4, 2021

(54) LASER CONTACT ABLATION FOR SEMICONDUCTOR PACKAGES AND RELATED METHODS

(71) Applicant: SEMICONDUCTOR COMPONENTS INDUSTRIES, LLC, Phoenix, AZ (US)

(72) Inventors: Francis J. CARNEY, Mesa, AZ (US); Michael J. SEDDON, Gilbert, AZ (US)

(73) Assignee: SEMICONDUCTOR COMPONENTS INDUSTRIES, LLC, Phoenix, AZ (US)

(21) Appl. No.: 16/862,222

(22) Filed: Apr. 29, 2020

(51) Int. Cl. H01L 21/311; H01L 21/56; H01L 21/268; H01L 23/485

(52) U.S. Cl. CPC H01L 21/31127; H01L 23/485; H01L 21/268; H01L 21/565

(57) ABSTRACT

Implementations of a semiconductor substrate may include a plurality of die including at least one contact; and a plurality of portions of an encapsulant on a surface of the semiconductor substrate, wherein each portion of the plurality of portions extends immediately above a plane of the at least one contact.

### BACKGROUND

### 1. Technical Field

Aspects of this document relate generally to semiconductor packages. More specific implementations involve thinned power semiconductor packages with a dual side metallization structure and methods of making such thinned power semiconductor packages.

### 2. Background

Semiconductor package fabrication processes may involve many steps. In some processes a wafer receives one or more layers, such as electrically conductive layers. Electrically conductive layers may be used to provide electrical contact areas of individual semiconductor devices singulated from the wafer. Further, in some processes the overall size of the semiconductor package may designed to be minimized.

### SUMMARY

Implementations of a semiconductor substrate may include a plurality of die including at least one contact; and a plurality of portions of an encapsulant on a surface of the semiconductor substrate, wherein each portion of the plurality of portions extends immediately above a plane of the at least one contact.

Implementations of semiconductor substrates may include one, all, or any of the following:

The plurality of portions of encapsulant may be formed through laser ablating the encapsulant over the at least one contact of the plurality of die.

The laser ablating further may include spot ablation over the at least one contact of the plurality of die.

The laser ablating further may include scanning ablation over the at least one contact of the plurality of die.

The laser ablating further may include bulk ablation over the at least one contact of the plurality of die.

The laser ablating further may include multi-pass ablation over the at least one contact of the plurality of die.

The at least one contact may be exposed by ablating the plurality of portions of the encapsulant over the plane.

Implementations of a method of forming a semiconductor package may include forming a plurality of electrical connectors on a first side of a wafer; and applying a mold compound to the first side of the wafer. The mold compound may encapsulate the plurality of electrical connectors. The method may include exposing the plurality of electrical connectors through the mold compound by ablating the mold compound immediately above each electrical connector of the plurality of electrical connectors with a laser.

Implementations of a method of forming a semiconductor package may include one, all, or any of the following:

Exposing the plurality of electrical connectors through the mold compound by ablating the mold compound with a laser further may include spot ablation over the plurality of electrical connectors.

Exposing the plurality of electrical connectors through the mold compound by ablating the mold compound with a laser further may include scanning ablation over the plurality of electrical connectors.

Exposing the plurality of electrical connectors through the mold compound by ablating the mold compound with a laser further may include bulk ablation over the plurality of electrical connectors.

Exposing the plurality of electrical connectors through the mold compound by ablating the mold compound with a laser further may include multi-pass ablation over the plurality of electrical connectors in multiple passes.

Implementations of a semiconductor package may include at least one electrical contact including a perimeter; and a mold compound raised above a largest planar area of the contact immediately around the perimeter of the at least one electrical contact.

Implementations of a semiconductor package may include one, all, or any of the following:

The at least one electrical contact may be exposed by ablating the mold compound over the largest planar area.

The ablating further may include spot ablation over the largest planar area of the contact around the perimeter of the at least one electrical contact.

The ablating further may include scanning ablation over the largest planar area of the contact around the perimeter of the at least one electrical contact.

The ablating further may include bulk ablation over the largest planar area of the contact around the perimeter of the at least one electrical contact.

The ablating further may include multi-pass ablation over the largest planar area of the contact around the perimeter of the at least one electrical contact.

The raising of the mold compound may be formed through laser ablating over the at least one electrical contact.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 illustrates a cross-sectional side view of a semiconductor package including a mold compound applied to a first side of a wafer;

FIG. 2 illustrates a cross-sectional side view of the semiconductor package including a backside metal layer coupled to a second side of the wafer;

FIG. 3 illustrates a cross-sectional side view of the semiconductor package, the mold compound being ablated by a laser;

FIG. 4 illustrates a cross-sectional side view of a semiconductor substrate after the mold compound has been fully ablated;

FIG. 5 illustrates a cross-sectional side view of a semiconductor package including a plurality of electrical contacts;

FIG. 6 illustrates a cross-sectional side view of the semiconductor package including a mold compound coupled over the electrical contacts; and

FIG. 7 illustrates a cross-sectional side view of the semiconductor package after the mold compound has been ablated over the electrical contacts.

### DESCRIPTION

This disclosure, its aspects and implementations, are not limited to the specific components, assembly procedures or method elements disclosed herein. Many additional components, assembly procedures and/or method elements known in the art consistent with the intended methods of ablation will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such methods of ablation, and implementing components and methods, consistent with the intended operation and methods.

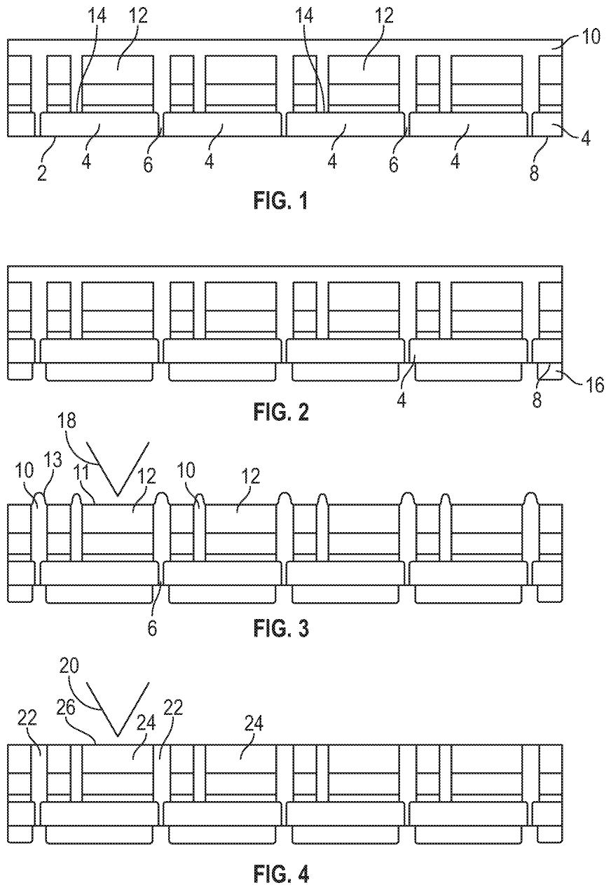

Referring to FIG. 1, a cross-sectional side view of a semiconductor package including a mold compound applied to a first side of a wafer is illustrated. The method of forming such a package includes forming a plurality of electrical connectors 12 on a first side 14 of a wafer 2 that includes a plurality of semiconductor die 4. As illustrated, the method may also include forming a plurality of recesses 6 into the first side 14 of the wafer 2 to a desired depth into the wafer 2. In various implementations, the depth of each recess of the plurality of recesses 6 may be less than 50 um, while in other implementations the depth may be 50 or more micrometers depending on the thickness of the wafer. In other method implementations, however, the method may not include a recess forming step, instead, the existing depth of the die streets into the wafer may be used as the recess for subsequent processing.

In various implementations, the plurality of recesses 6 may be formed with, by non-limiting example, a saw, a laser, a plasma etch, a chemical etch, or any other method for forming a recess in a wafer. In still other implementations, the sidewalls of the plurality of recesses 6 may be slightly patterned or ridged which may facilitate adhesion of a mold compound to the sidewalls of the plurality of recesses 6. In various implementations, the plurality of recesses 6 may be positioned in the wafer 2 so that they are between the semiconductor devices in the wafer. In other implementations, the plurality of recesses 6 may be positioned in the wafer so they are between the various semiconductor die formed in/on the wafer.

Still referring to FIG. 1, as illustrated, the method also includes applying a mold compound 10 to the first side 14 of the wafer 2. In various implementations, the mold compound 10 encapsulates the plurality of electrical connectors 12 and fills the space of the plurality of recesses 6 thus coupling the mold compound 10 to the die 4. In various implementations, the mold compound may include, by non-limiting example, an epoxy, an acrylic, a resin, a filler, a pigment, a polymer, any combination thereof, or any other type of component of a material capable of filling the recesses. The mold compound may be applied using, by non-limiting example, a liquid dispensing technique, a transfer molding technique, a vacuum molding technique, a glob top molding technique, a compression molding technique, or any other mold compound application process.

In various implementations, and as is illustrated by FIG. 1, the mold compound 10 may cover sides of the die. In particular implementations, the mold compound 10 may cover five sides of the three-dimensional die (for a die that is rectangular). In the implementation illustrated in FIG. 1, the entirety of the five sides of the die are covered by the mold compound 10. However, in other implementations the sides of the die 4 that extend across the thickness of the die may only partially be covered by a mold compound 10, while in still other implementations the mold compound 10 may not cover the sides of the die 4 that extend across the thickness at all. In various implementations, a portion of a second side of the die may be covered by a mold compound. The mold compound covering the second side of the die 4 may be the same or a separate mold compound from the mold compound 10. In such implementations, the mold compound 10 may also cover the sides of a backside metal layer (16 in FIG. 2) in implementations where the backside metal layer is included and is the same length as or shorter than the length of the die 4.

Still referring to FIG. 1, a second side 8 of the wafer 2 is thinned to the desired depth of the plurality of recesses 6. In various implementations, the thinned wafer 2, or plurality of die 4, may be less than about 50 um thick, while in other implementations the thinned wafer, or plurality of die, may be more than about 50 or more um thick. In some implementations the thinned wafer 2 may be less than about 25 um thick, less than about 10 um thick, or less than about 5 um thick. The mold compound 10 coupled to the first side 14 of the wafer 2 and within the plurality of recesses 6 may facilitate thinning the wafer 2 by providing structural support to the wafer. In other implementations, the second side 8 of the wafer may not be thinned to the depth of the desired recesses 6. In this manner, the die of each semiconductor package may take on a stepped shape upon final singulation of the wafer 2.

In various implementations, the semiconductor packages disclosed herein may include power semiconductor devices, however, in other implementations other semiconductor device types (transistors, microprocessors, passive components, etc.) may be included in the semiconductor packages. In various implementations, the semiconductor package includes a die. The die may be a silicon die, and in such implementations, the silicon die could be any type of silicon die including, by non-limiting example, an epitaxial silicon die, silicon-on-insulator, polysilicon, silicon carbide any combination thereof, or any other silicon-containing die material. Further, it is also understood that in various implementations a die other than a silicon-containing die may be used, such as, by non-limiting example, gallium arsenide, ruby, sapphire, a metal-containing die, or any other semiconductor die type.

Referring to FIG. 2, a cross-sectional side view of an implementation of a semiconductor package including a backside metal layer coupled to a second side of the wafer is illustrated. The method of forming the package that includes a backmetal may also include coupling a backside metal layer 16 to the second side 8 of the wafer. In various implementations, the backside metal layer (backmetal) 16 may be coupled over the semiconductor die 4. However, in various implementations, the backmetal layer may not be included at all, and so the process of coupling the backmetal may be dispensed with. In various implementations, the backside metal layer 16 may be a thick backside metal layer and in particular implementations, may be as thick as or thicker than the thickness of the thinned wafer. In various implementations, the backside metal layer 16 may be, by non-limiting example, copper, aluminum, tin, silver, gold, titanium, nickel, any combination thereof, or any other metal or metal alloy. It is also understood that any other electrically and/or thermally conductive material, including any metal or metal alloy disclosed herein, may be used.

In particular implementations, the backside metal layer may include, by non-limiting example, Ti/Ni/Cu, Ti/Cu, TiW/Cu, or any other type of metal stack or metal alloy including copper. In various implementations, and as illustrated by FIG. 2, the length of the backside metal layer 16 may be less than the length of the die 4. In such implementations, the die 4 may overhang the backside metal layer 16. In other implementations, the length of the backmetal layer 16 may be substantially the same as the length of the die 4 with the sides of the backmetal layer coextensive with the sides/perimeter of the die. In still other implementations, the back metal layer may extend beyond the sides/perimeter of the die 4. In various implementations, the back metal layer may be patterned.

In implementations where a back metal layer is employed (and also in implementations where it is not used), a stress relief etch may be utilized in various method implementations. This stress relief etch may be carried out after backgrinding and with or without back metal. In some implementations, the stress relief wet etching may take place after protecting the front side (die side) of the semiconductor substrate. The stress relief etching may reduce the backside damage to the semiconductor substrate that is caused by the backgrinding process. The use of the stress relief etching may also facilitate adhesion of any back metal applied to the ground surface. While the use of wet etching has been disclosed, in various implementations the use of dry etching could be employed in various implementations.

Whether the particular thinned die or wafer utilizes a back metal (and for some, before backmetal is applied to the thinned die or wafer), the various thinned die/wafers disclosed in this document have one or more electrical contacts exposed. Referring to FIG. 3, a cross-sectional side view of the semiconductor package, the mold compound being ablated by a laser 18 is illustrated. As illustrated, the method of forming the semiconductor package further includes exposing the plurality of electrical connectors 12 through the mold compound 10 by ablating the mold compound 10 with a laser 18 that is over the electrical connectors 12. As a result of the process of performing ablation, a plurality of portions 13 of remaining encapsulant/mold compound 10 are formed through laser ablating the encapsulant/mold compound 10 over a contact 12 of each of the plurality of die 4. In various implementations, as illustrated, the ablation leaves portions of mold compound 10 that extend above the surfaces of the electrical connectors 12.

In various implementations, the ablation may be spot ablation. In implementations of spot ablation, the ablation may take place through targeting specific locations across the wafer where electrical connectors are located and then removing the mold compound to expose those electrical connectors. In implementations of scanning ablation, a scanning pattern is employed where the implement (laser, water jet etc.) follows a predetermined pattern across the wafer while activated, ablating material as it passes. In implementations of bulk ablation the ablation implement scans across all or substantially all of the surface of the wafer (for those ablation techniques that are utilize scanning) or works directly to ablate all or substantially all of the mold compound on the wafer surface. For implementations of multi-pass ablation, the ablation implement may be employed to pass over at least a portion of a previously ablated surface one or more additional times to further ablate the material.

For situations where laser ablation is employed, a single laser light beam may used to perform the ablation. In other implementations, multiple laser beams may be used to simultaneously ablate by indexing across the wafer on opposite portions of the wafer. In various implementations, these laser beams may index for at least part of the time spaced apart across a midpoint of the wafer. The particular alignment/feed speeds, etc. of the laser beam(s) in various implementations where single or dual laser light beams are employed may be determined by a wide variety of factors, including, by non-limiting example, laser power, optical configuration, throughput, mold compound thickness, and any other factor driven by tool configuration, throughput, or process effectiveness.

In various implementations, two laser beams may begin on opposite sides of the wafer and index towards each other toward the midpoint; in others, they may begin adjacent to the midpoint, and index away from each other. The spacing of the beams may be as close as adjacent electrical contacts may be any number of electrical contact locations away from each other. In this implementation, and in all other multiple laser beam implementations disclosed in this document, the two or more laser beams may have the same characteristics, or may be different from one another in one or more of the following respects, by non-limiting example: laser type, laser wavelength, spot size, power, pulse energy, pulse width, repetition rate/frequency, indexing speed, dwell time, ablation depth into the mold compound, numerical aperture, average power, and any other desired laser characteristic. Also, the two or more laser beams may be generated by the same or different laser devices in various implementations.

In various implementations, the path followed by the single or dual laser beams may be an alternating single pass path, where the laser indexes across the wafer first in the y direction, over in the x direction, and then indexes in the opposite y direction in various steps across the wafer. In various implementations, the spacing of steps in the x direction may the same. In other implementations, however, the spacing of steps may vary across the wafer, either for an initial period, or for the entire distance across the wafer in the x direction, depending on how the mold compound ablates or the location of the electrical connectors.

In some implementations, the single/dual laser beams may employ an intersecting dual pass path. In various versions of the paths, the paths are first irradiated by the laser during the first pass, and then irradiated again by the laser during the second pass. The use of dual pass paths may allow for, by non-limiting example, the enhancement of the ablation of the mold compound, improve sidewall shape, reduce risk of burning/carbonization of the material of the material of the mold compound, reduce flow of the mold compound under the heat of the laser, permit sufficient cooling time, or otherwise adjust the structure of the ablated mold compound between passes. This may, in turn, enhance the thickness or other desired characteristics of the damage layer formed.

In various implementations, single pass spiral paths may be employed. In various implementations, various combinations and arrangements of spiral paths may be employed, such as multi-pass paths, and spirals of various shapes and designs (more tightly arranged spirals at the beginning or end of the spiral) and various overlapping arrangements of spirals may be used. Also, for spiral (and alternating/intersecting paths), where pulsed rather than continuous wave laser irradiation is employed, the frequency of pulses of laser irradiation along the path may be varied along the path (more points at the beginning, middle, or end of the path, or in different portions of the path than in other portions).

In various implementations where intersecting dual pass paths are employed, the second pass may be angled rather than executed at about 90 degrees to the first pass. The angle at which the second pass is performed relative to the first pass may be determined by various factors, including, by desired throughput rates through the laser process tool, location of the various electrical connectors, the ablation characteristics of the particular mold compound being ablated, and any other process characteristic that affects the speed or efficacy of the laser ablation process. In various implementations, some of the locations along the path of laser irradiation may be common between the first pass and the second pass while other locations are unique to one of the passes.

In some other implementations of a dual intersecting pass path all of the locations along the second pass may be oriented substantially parallel with the locations of the first pass and none are shared between the two passes. The use of this technique may, in various implementations, assist with allowing the mold compound to react to the damage of the first pass before the second pass is carried out. In some implementations, the wafer may be laser ablated using a dual intersecting pass path which is executed in the reverse order another path. In various implementations, the dual pass path may be executed in varying orders from substrate to substrate as the mold compound ablation may not be affected by the order of execution of the paths. In other implementations, the order in which the dual pass path is executed may affect the characteristics of the mold compound being ablated or remaining after ablation, so all substrates have to be processed in the same order. Where the mold compound ablation and/or characteristics of the remaining mold compound depend on the execution order of the dual pass path, this may be caused by a wide variety of factors, including, by non-limiting example, the material characteristics of the particular mold compound being ablated, the glass transition temperature of the mold compound, the oxidation rate of the mold compound, the absorption percentage of light by the mold compound for the laser length being used, or any other material characteristics of the mold compound and/or the laser light.

Many different single pass, dual pass, and more than two pass paths for processing wafers may constructed using the principles disclosed in this document. Also, many different intersecting, spiral, alternating, alternating+spiral, random, and semi-random paths may be constructed using the principles disclosed herein. What paths are employed will depend on many of the different laser and mold compound material factors desired, as well as the locations of the electrical contacts across the wafer.

As illustrated in FIG. 3, the wafer 2 may thus include a plurality of die 4 with at least one contact/electrical connector 12 and a plurality of portions of an encapsulant/mold compound 10 on a surface 11 of the semiconductor substrate, or electrical connectors 12. As illustrated, each portion of the plurality of portions extends above a plane of the at least one contact/electrical connector 12. As an alternative way of describing the resulting structure, at least one electrical contact/connector 12 includes a perimeter, and the remaining mold compound 10 is raised above a largest planar area of the contact 12 around the perimeter of the at least one electrical contact/connector 12. After ablation, the method may also include singulating the mold compound 10 through the plurality of recesses 6 into a plurality of semiconductor packages, in various implementations.

Referring to FIG. 4, a cross-sectional side view of a semiconductor substrate after the mold compound has been fully ablated is illustrated. The method of forming the semiconductor package may also further include ablating the mold compound 22 with the laser 20 fully, so that no portions of mold compound 22 remain above the surfaces of the electrical connectors 24, or such that the mold compound 22 is substantially coplanar with a surface 26 of the electrical connectors 24. While in the foregoing description the use of a laser to perform the ablation has been illustrated, in other implementations, other methods of ablation like those disclosed in this document may be employed.

In some method implementations, the method may further include ablating one or more of the portions 13 (referring to FIG. 3). In some implementations, the ablation of the one or more portions 13 may fully remove the portions (i.e., eliminate their ability to extend above the plane created by at least one of the electrical connectors 24). In other implementations, the ablation of the one or more portions may partially remove the portions (leaving a part of the portions extending above the plate created by the at least one electrical connectors 24). In yet other implementations, the ablation may change a sidewall profile or other shape of the portions, such as, by non-limiting example, a continuity of the portions around a perimeter of an electrical contact, grooving the portions, shaping an edge of the portions, or any other effect of ablating a mold compound.

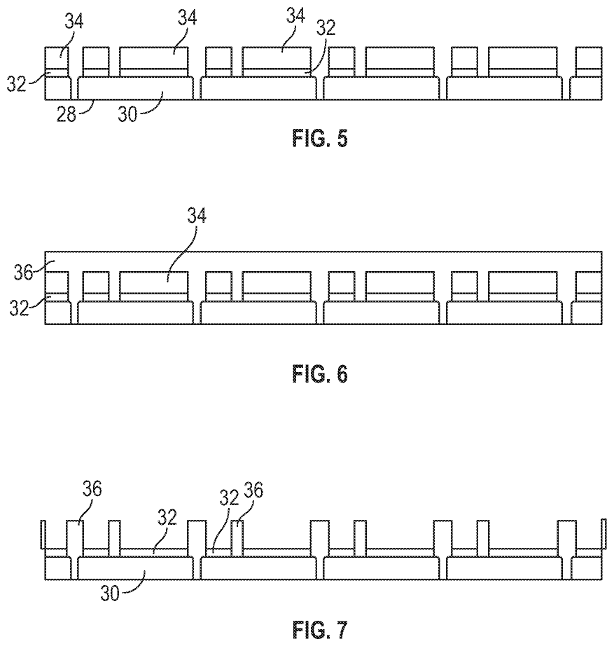

Referring to FIG. 5, a cross-sectional side view of a semiconductor package including a plurality of electrical contacts is illustrated. As illustrated, a plurality of semiconductor die 30 are coupled to a wafer 28. One or more contacts of a plurality of electrical contacts/connectors 32 are coupled to a first side of each semiconductor die 30, as illustrated. In addition, as illustrated, a masking layer 34 is patterned over each electrical contact 32. In various implementations, the masking layer may comprise a photoresist layer.

Referring to FIG. 6, a cross-sectional side view of the semiconductor package including a mold compound coupled over the electrical contacts is illustrated. As illustrated, a mold compound 36 is deposited over the electrical contacts 32 and masking layer 34. In various implementations, the mold compound may also fill a plurality of recesses around the semiconductor dies and the electrical contacts 32. In various implementations, the mold compound may include, by non-limiting example, an epoxy, an acrylic, a resin, a filler, a pigment, a polymer, any combination thereof, or any other type of component of a material capable of filling the recesses. The mold compound may be applied in various implementations using a release tape and a formed mold press. While in the implementation illustrated in FIG. 6, the mold compound is illustrated as covering the upper surfaces of the masking layer 34, in other implementations, the mold compound may be applied so that the upper surfaces of the masking layer 34 are exposed after molding is completed.

In various implementations, and as is illustrated by FIG. 6, the mold compound 36 may cover various sides of the die. In particular implementations, the mold compound 36 may cover five sides of the three-dimensional die (for a die that is rectangular). In the implementation illustrated in FIG. 6, the entirety of the five sides of the die are covered by the mold compound 36. However, in other implementations the sides of the die 30 that extend across the thickness of the die may only partially be covered by a mold compound 36, while in still other implementations the mold compound 36 may not cover the sides of the die 30 that extend across the thickness at all. In various implementations, a portion of a second side of the die may be covered by a mold compound. The mold compound covering the second side of the die 30 may be the same or a separate mold compound from the mold compound 36. In such implementations, the mold compound 36 may also cover the sides of a backside metal layer in implementations where the backside metal layer is included and is the same length as or shorter than the length of the die 30.

Referring to FIG. 7, a cross-sectional side view of the semiconductor package after the mold compound has been ground down/level to the surface of the masking layer 34 and the material of the masking layer 34 has been removed. In various implementations, the masking material may be removed in various ways, including, by non-limiting example, dissolving, wet etching, dry etching, plasma etching, lifting off through adhering to a lift-off film, light exposure following by dissolving, or any other method of removing an organic material. As illustrated, while the mold compound 36 extends around the perimeter of each electrical contact electrical contact 32, none of the material of the mold compound 36 is over the electrical contact as it has been masked off. As illustrated, the mold compound 36 may, in various implementations, fill recesses in between each semiconductor die 30, and may extend immediately above a plane of the electrical contact 32. In this implementation, the sidewalls of the mold compound 36 around the electrical contact 32 are straight or substantially straight as a consequence of using the masking process in comparison with the rounded shape of the sidewalls of the mold compound in FIG. 3 where laser ablation is used to remove the mold compound.

In various implementations, alignment of the substrate or wafer prior to the ablation or etching process may take place using a variety of methods. For example, notches may be formed along the edge of the wafer that permit alignment of the wafer to be carried out prior to ablation beginning. In other implementations, an infrared camera may be used to identify alignment features in the side of the wafer opposite the site being ablated (a backside of the wafer in various implementations). In other implementations, at least three areas on the topside of the wafer may not be encapsulated or only partially encapsulated to expose alignment features for use in alignment. In yet other implementations, another imaging technique may be employed to penetrate below or through the mold compound like X-rays to allow the alignment system to identify the alignment features. A wide variety of structures and systems may be employed to ensure the wafer/substrate is aligned as needed to perform the ablation/etching process in the various implementations disclosed herein.

In other method and process implementations, laser ablation or the other material removal methods disclosed herein may be used in combination with other methods of partially thinning the mold compound prior to ablating/etching the material. For example, grinding may be used to partially thin the mold compound prior to laser ablating using any method disclosed herein. In other implementations, polishing or lapping may be employed prior to laser ablating or etching using any method disclosed herein. A wide variety of process variations may be constructed using the principles disclosed herein.

In places where the description above refers to particular implementations of ablation methods and implementing components, sub-components, methods and sub-methods, it should be readily apparent that a number of modifications may be made without departing from the spirit thereof and that these implementations, implementing components, sub-components, methods and sub-methods may be applied to other ablation methods and related implementing components.

1. A semiconductor substrate comprising:
a plurality of die comprising at least one exposed contact directly coupled to a first side of each of the plurality of die, the first side opposing a second side of the plurality of die directly coupled with a backmetal layer; and
a plurality of portions of an encapsulant on a surface of the semiconductor substrate, wherein each portion of the plurality of portions extends immediately above a plane of the at least one exposed contact.

2. The semiconductor substrate of claim 1, wherein the plurality of portions of encapsulant are formed through laser ablating the encapsulant originally over the at least one exposed contact of the plurality of die.

3. The semiconductor substrate of claim 2, wherein the laser ablating further comprises spot ablation.

4. The semiconductor substrate of claim 2, wherein the laser ablating further comprises scanning ablation.

5. The semiconductor substrate of claim 2, wherein the laser ablating further comprises bulk ablation.

6. The semiconductor substrate of claim 2, wherein the laser ablating further comprises multi-pass ablation.

7. (canceled)

8. A method of forming a semiconductor package comprising:
forming a plurality of electrical connectors on a first side of a wafer, the first side opposing a second side of the wafer configured to directly couple with a backmetal layer;
applying a mold compound to the first side of the wafer, wherein the mold compound encapsulates the plurality of electrical connectors; and
exposing the plurality of electrical connectors through the mold compound by ablating the mold compound immediately above each electrical connector of the plurality of electrical connectors with a laser.

9. The method of claim 8, wherein exposing the plurality of electrical connectors through the mold compound by ablating the mold compound with a laser further comprises spot ablation over the plurality of electrical connectors.

10. The method of claim 8, wherein exposing the plurality of electrical connectors through the mold compound by ablating the mold compound with a laser further comprises scanning ablation over the plurality of electrical connectors.

11. The method of claim 8, wherein exposing the plurality of electrical connectors through the mold compound by ablating the mold compound with a laser further comprises bulk ablation over the plurality of electrical connectors.

12. The method of claim 8, wherein exposing the plurality of electrical connectors through the mold compound by ablating the mold compound with a laser further comprises multi-pass ablation over the plurality of electrical connectors in multiple passes.

13. A semiconductor package comprising:
at least one electrical contact comprising a perimeter, the at least one electrical contact directly coupled to a first side of a die opposing a second side of the die directly coupled with a backmetal layer; and
a mold compound raised above a largest planar area of the contact immediately around the perimeter of the at least one electrical contact;
wherein the perimeter of the at least one electrical contact is exposed through the mold compound.

14. The semiconductor package of claim 13, wherein the at least one electrical contact is exposed by ablating the mold compound over the largest planar area.

15. The semiconductor package of claim 14, wherein the ablating further comprises spot ablation over the largest planar area of the contact around the perimeter of the at least one electrical contact.

16. The semiconductor package of claim 14, wherein the ablating further comprises scanning ablation over the largest planar area of the contact around the perimeter of the at least one electrical contact.

17. The semiconductor package of claim 14, wherein the ablating further comprises bulk ablation over the largest planar area of the contact around the perimeter of the at least one electrical contact.

18. The semiconductor package of claim 14, wherein the ablating further comprises multi-pass ablation over the largest planar area of the contact around the perimeter of the at least one electrical contact.

19. The semiconductor package of claim 13, wherein the raising of the mold compound is formed through laser ablating over the at least one electrical contact.
